(19) United States
(12) Patent Application Publication
(10) Pub. No.: US 2009/0032088 A1
(43) Pub. Date: Feb. 5, 2009

(54) Sealants for Solar Energy Concentrators and Similar Equipment

(76) Inventor: Mario Rabinowitz, Redwood City, CA (US)

Correspondence Address: MARIO RABINOWITZ, 715 LAKEMEAD WAY, REDWOOD CITY, CA, 94062, US

(21) Appl. No.: 11/833,965

(22) Filed: Aug. 3, 2007

(51) Int. Cl. H01L 31/042; C09J 183/04

(52) U.S. Cl. 136/251; 156/333

(57) ABSTRACT

This invention increases the longevity and performance of solar concentrators, optical switches; and reflection, illumination, and projection equipment in general. To achieve long lifetimes this equipment is sealed to prevent egress of internal lubricant or ingress of undesirable fluids. The rotational elements are sealed to increase their abrasion resistance. Many plastic materials if not sealed as taught in the instant invention are vulnerable to UV degradation, static dust attraction, poor weatherability, and ineffective abrasion resistance resulting in damage in the field and during cleaning. This invention improves the above optical equipment by sealing them with a tough, thin, transparent film. Even in equipment with no internal lubricant, tailored sealants as described in the instant invention can improve the performance of the mirrored elements, Fresnel lenses, and parabolic reflectors. For all the devices, the sealant of the instant invention hardens the surface to prevent scratching, and furthermore can be tailored to be an anti-fogant to keep water vapor off.

### FIELD OF THE INVENTION

The instant invention relates to essentially optically transparent sealants for Solar Energy Concentrators and the mirrored elements (balls) within; and similar equipment such as Optical Switches [cf. M. Rabinowitz U.S. Pat. No. 6,976,445]; and Dynamic Reflection, Illumination, and Projection equipment [cf. M. Rabinowitz U.S. Pat. No. 7,130,102]. The Solar Energy Concentrators may be of the Fresnel reflector type[cf. M. Rabinowitz U.S. Pat. No. 7,133,183], Fresnel lens type, parabolic reflectors (three-dimensional, and two-dimensional troughs), etc. Method and apparatus for producing the sealants, and applying the sealants (sealant implementation) are also disclosed.

### BACKGROUND OF THE INVENTION

This invention provides a better means to achieve low cost affordable solar energy. It does so by greatly increasing the longevity and performance of solar concentrators, optical switches; and reflection, illumination, and projection equipment in general. In order to minimize friction during the alignment rotation of the mirrored elements within, these devices utilize a lubricating fluid surrounding these elements. To achieve long lifetimes, particularly in hostile environments, it is judicious to seal these devices (equipment) to prevent egress of the lubricant or ingress of undesirable fluids. Even in equipment with no internal lubricant, tailored sealants as described in the instant invention can improve the performance of the mirrored elements, Fresnel lenses, and parabolic reflectors.

This invention improves all this equipment by sealing them with a tough, thin, transparent film. This sealant film not only helps to seal these devices, but increases their lifetime capabilities in several ways. For those devices that have internal lubrication [e.g. U.S. Pat. Nos. 7,133,183, 7,130,102, and 6,976,445] the sealant film acts to keep the lubricant in, and also prevents infiltration of undesirable external fluids. For all the devices, the sealant of the instant invention hardens the surface to prevent scratching, and furthermore can be tailored to be an anti-fogant to keep water vapor off. A hard sealant film around the mirrored elements can also increase their useful life.

Many years of privately and publicly funded research have yet to produce a cost-effective and durable highly specular reflecting material for solar energy applications. Outdoor weatherability and cleaning of the material without damage also continues to be a pressing problem. Many plastic materials if not sealed as taught in the instant invention are vulnerable to UV degradation, static dust attraction, poor weatherability, and ineffective abrasion resistance resulting in damage in the field and during cleaning.

### INCORPORATION BY REFERENCE

In a solar energy application (as well as other functions), elements in the form of transparent reflecting micro-balls and other shapes are a critical feature of a unique solar concentrator which directs sunlight to a receiver as described in the following patents and copending patent applications related to this case. The following U.S. patents, and Solar Journal publication are fully incorporated herein by reference.
1. U.S. Pat. No. 7,247,790 by Mario Rabinowitz, “Spinning Concentrator Enhanced Solar Energy Alternating Current Production” issued on Jul. 24, 2007.
2. U.S. Pat. No. 7,187,490 by Mario Rabinowitz, “Induced Dipole Alignment Of Solar Concentrator Balls” issued on Mar. 6, 2007
3. U.S. Pat. No. 7,133,183 by Mario Rabinowitz, “Micro-Optics Solar Energy Concentrator” issued on Nov. 7, 2006.
4. U.S. Pat. No. 7,130,102 by Mario Rabinowitz, “Dynamic Reflection, Illumination, and Projection” issued on Oct. 31, 2006.
5. U.S. Pat. No. 7,115,881 by Mario Rabinowitz and Mark Davidson, “Positioning and Motion Control by Electrons, Ions, and Neutrals in Electric Fields” issued on Oct. 3, 2006.
6. U.S. Pat. No. 7,112,253, by Mario Rabinowitz, “Manufacturing Transparent Mirrored Mini-Balls for Solar Energy Concentration and Analogous Applications” issued on Sep. 26, 2006.
7. U.S. Pat. No. 7,077,361, by Mario Rabinowitz, “Micro-Optics Concentrator for Solar Power Satellites” issued on Jul. 18, 2006.
8. U.S. Pat. No. 6,988,809 by Mario Rabinowitz, “Advanced Micro-Optics Solar Energy Collection System” issued on Jan. 24, 2006.
9. U.S. Pat. No. 6,987,604 by Mario Rabinowitz and David Overhauser, “Manufacture of and Apparatus for Nearly Frictionless Operation of a Rotatable Array of Micro-Mirrors in a Solar Concentrator Sheet” issued on Jan. 17, 2006.
10. U.S. Pat. No. 6,975,445 by Mario Rabinowitz, “Dynamic Optical Switching Ensemble” issued on Dec. 13, 2005.
11. U.S. Pat. No. 6,964,486 by Mario Rabinowitz, “Alignment of Solar Concentrator Micro-Mirrors” issued on Nov. 15, 2005.
12. U.S. Pat. No. 6,957,894 by Mario Rabinowitz and Felipe Garcia, “Group Alignment Of Solar Concentrator Micro-Mirrors” issued on Oct. 25, 2005.
13. U.S. Pat. No. 6,843,73 by Mario Rabinowitz and Mark Davidson, “Mini-Optics Solar Energy Concentrator” issued on Jan. 18, 2005.
14. U.S. Pat. No. 6,738,176 by Mario Rabinowitz and Mark Davidson, “Dynamic Multi-Wavelength Switching Ensemble” issued on May 18, 2004.
15. U.S. Pat. No. 6,698,693 by Mark Davidson and Mario Rabinowitz, “Solar Propulsion Assist” issued on Mar. 2, 2004.
16. U.S. Pat. No. 6,612,705 by Mark Davidson and Mario Rabinowitz, “Mini-Optics Solar Energy Concentrator” issued on Sep. 2, 2003.
17. Solar Energy Journal, Vol.77, Issue #1, 3-13 (2004) “Electronic film with embedded micro-mirrors for solar energy concentrator systems” by Mario Rabinowitz and Mark Davidson.

### DEFINITIONS

“admix” means to mix one thing together with another.

“Bonded hydrophobic layer” as used herein means that the hydrophobic layer remains bound to the Substrate Binder layer, as determined by a contact angle test, even after washing that surface with isopropanol. If the hydrophobic layer is not bonded, then washing that layer in isopropanol solution will remove the majority thereof and the contact angle will be substantially decreased. If one uses a hydrophobic layer, it has to be the outermost layer. If there is sufficient sealing by the substrate binder layer and a hydrophobic layer is not necessary, then the substrate binder layer is sufficient as the outermost layer, and no other layers are necessary.

“Chelate” is a chemical compound in the form of a heterocyclic ring, containing a metal ion attached by coordinate bonds to at least two nonmetal ions.

“Collector” or “Receiver” as used herein denotes any device for the conversion of solar energy into other forms such as electricity, heat, pressure, concentrated light, etc.

“Concentrator” as used herein in general is a micro-mirror system for focussing and reflecting light. In a solar energy context, it is that part of a solar Collector system that directs and concentrates solar radiation onto a solar receiver or other device. As used herein, concentrator refers to an ensemble of focussing planar mirrors which acts as a thin almost planar mirror constructed with stepped varying angles so as to have the optical properties of a much thicker concave mirror. Heuristically, it can somewhat be thought of as the projection of thin variable-angular segments of small portions of a thick mirror upon a planar surface. It is a focusing planar reflecting surface much like a planar Fresnel lens is a focusing transmitting surface.

“Contact angle” as used herein is a test of hydrophobicity of the sealing of a surface in which a water droplet is placed on the surface and the degree of spreading is measured as the contact angle between the surface and the side of the droplet. Contact angles greater than 45 degrees represent less spreading, and indicate a hydrophobic surface. Hydrophilic surfaces have contact angles that approach zero.

“Diamond-like carbon” is the generic name for a very hard family of materials in which the molecular backbone is primarily carbon, with some hydrogen attached.

“Elastomer” is a material such as synthetic rubber or plastic, which at ordinary temperatures can be stretched substantially under low stress, and upon immediate release of the stress, will return with force to approximately its original length. Silicone elastomers have exceptional ability to withstand ultraviolet light degradation.

“Element” is a rotatable mirrored component of a concentrator, such as a ball, cylinder, disk, semi-sphere, etc.

“Equipment” is used herein as a generic term for Solar Energy Concentrators and the mirrored elements (balls) within; and similar equipment such as Optical Switches; and Dynamic Reflection, Illumination, and Projection devices. The Solar Energy Concentrators may be of the Fresnel reflector type, Fresnel lens type, parabolic reflectors (three-dimensional, and two-dimensional troughs), etc.

“Focussing planar mirror” is a thin almost planar mirror constructed with stepped varying angles so as to have the optical properties of a much thicker concave (or convex) mirror. It can heuristically be thought of somewhat as the projection of thin equi-angular segments of small portions of a thick mirror upon a planar surface. It is a focusing planar reflecting surface much like a planar Fresnel lens is a focusing transmitting surface. If a shiny metal coating is placed on a Fresnel lens it can act as a Fresnel reflector.

“Hydrolyze” means to breakdown a compound by chemical reaction with water.

“Hydrophobic” means tending to repel or fail to mix with water. Hydrophillic is the opposite of hydrophobic.

“Inert gas” as used means a gas that is relatively unreactive in a given environment such as argon, xenon, neon, helium, krypton, and nitrogen.

“Lexan” is General Electric's trade name for a group of polyesters formed from carbonic acid, and generally called polycarbonate (PC). Polycarbonate has excellent mechanical properties while at the same time it has an ease for molding and extrusion. Lexan has good dimensional stability, good resistance to creep, and a high distortion temperature.

“Lubricant” or “lubricious” as used herein is intended to encompass materials that accomplish the intended task of forming a hydrophobic wear-resistant surface on the article, whether or not those materials are conventionally employed as lubricants.

“Lucite” is DuPont's trade name for its transparent acrylic plastic and resins with no definite melting point.

“Mirror” as used herein refers to a highly reflective smooth surface (smooth on a size scale small compared to the wavelength of incident light). The smoothness achieves specular reflection.

“Monolayer” as used herein is a layer one molecule thick. A monolayer occupies all of the available surface.

“Optical communication” as used herein means that an optical signal comes into the equipment, and/or an optical signal goes out of the equipment

“Optically transparent” as used herein means transparent to light at least in the range of about 2000 to approximately 7500 Angstroms wavelength. Thus a substantial portion of wavelengths from visible to infrared light passes through the sealant; and ideally ultraviolet light also.

“Plastic” is a polymeric material (usually organic) which can be shaped by flow. The resin is the homogeneous starting material, whereas the “plastic” refers to the final product also containing fillers, plasticizers, stabilizers, etc.

“Plasticizer” is added to a material to make it softer, more flexible, or more moldable. It is also called a flexibilizer because it is an additive that gives an otherwise rigid plastic flexibility.

“Plastic paint” is a paint composed of a plastic in a solvent such that when the solvent is removed as by vaporization, a thin film of the plastic remains on the surface.

“Plexiglass” is a transparent plastic made from methyl methacrylate, similar to Lucite. Both can readily be made in sheet form.

“Sealant” as used herein includes but is not limited to sealing in lubricants and volatiles inside equipment, as well as preserving the equipment surface from wear, abrasion, ultraviolet light, heat, and other degradation processes.

“Sealant implementation” may be accomplished by conventional methods such as dipping, spraying, spin coating and flow coating, brushing, roll coating, chemically, by vacuum deposition, by plasma-enhanced chemical vapor deposition, and other art-recognized techniques.

“Silicone” as used herein refers to a heat-stable, rubber-like elastomer that is a water repellent, semiorganic polymer of organic radicals attached to silicon containing molecules, such as dimethyl silicone. Silicone elastomers are an excellent material within which to embed the mirrored balls or cylinders, because of their durability with respect to ultraviolet light and general resiliency among other reasons.

“Substrate” is the outside surface of the equipment which is to be sealed. The substrate shape is not critical, and the substrate may be flat, curved, patterned, etc., along any portion thereof, including the portion on which the substrate binder layer is deposited. The substrate may be formed of a single material or a plurality of materials and have multiple layers, as in a laminated substrate.

“Substrate Binder layer” is the layer that goes directly on and bonds with the surface of the equipment. The Substrate Binder layer facilitates bonding of the outer surface layer of the sealant to the equipment. This layer is preferably capable of forming strong bonds with both the substrate and the outer sealant layer.

“Substrate material” as used herein may be formed of any polymeric or plastic material. Illustrative materials include polyacrylate, polyester, polyethylene, polypropylene, polyamides, polylmides, polycarbonate, epoxy, phenolic, acrylonitrile-butadiene-styrene and acetal plastics. The mirrored balls (elements) are preferably formed of polycarbonate or polyacrylate resin such as poly-methyl methacrylate) because of their excellent physical, mechanical and chemical properties. The substrates may contain various additives such as fillers, antioxidants, plasticizers and the like, in accordance with known techniques.

“Surfactant” is a substance that reduces the surface tension of a liquid in which it is dissolved.

“Thermoplastic” refers to materials with a molecular structure that will soften when heated and harden when cooled. This includes materials such as vinyls, nylons, elastomers, fuorocarbons, polyethylenes, styrene, acrylics, cellulosics, etc.

“Thixotropic” refers to the property of a material to become less viscous when subjected to an applied mechanical stress. For example some gels become liquid when they are stressed.

### SUMMARY OF THE INVENTION

It is an aspect of the instant invention to provide an optically transparent sealant with a wear resistant surface for solar concentrators, optical switches; and reflection, illumination, and projection devices in general. Such optical equipment will herein simply be referred to as “equipment.”

It is another aspect of the present invention to increase the longevity and performance of optical equipment.

An aspect of this invention is to provide equipment with a tough, thin, transparent sealant film. This film helps to seal these devices and increases their lifetime. For those devices that have internal lubrication [e.g. U.S. Pat. Nos. 7,133,183, 7,130,102, and 6,976,445] the sealant acts to keep the lubricant in, and also prevents infiltration of undesirable external fluids.

A further aspect of the instant invention is to seal the surface of the equipment to prevent scratching during normal usage, and during cleaning.

Another aspect of the present invention is to provide equipment with an anti-fogant to keep water vapor off.

Yet another aspect of this invention in accordance with the foregoing is to form a hard antiabrasive, optically transparent outer surface on a polymeric substrate of the equipment. A lubricious hydrophobic sealing layer is bonded to the substrate. The lubriciuous hydrophobic outer surface sealing is preferably formed of a hydrophobic organic lubricant selected from the group comprised of fluorocarbons, fatty acids, and fatty acid esters.

A corresponding aspect of this invention in accordance with the foregoing is to form a hard antiabrasive, optically transparent outer surface surrounding each ball or element of those solar concentrators (and other optical devices) which operate by means of an ensemble of such elements [cf. U.S. Pat. Nos. 7,133,183, 7,130,102, and 6,976,445]. A longer, lower friction lifetime is thus provided for such equipment.

Another aspect of the instant invention is to provide a superior sealant for all kinds of solar devices such as Fresnel lens, parabolic mirror, and parabolic trough concentrators.

Other aspects and advantages of the invention will be apparent in a description of specific embodiments thereof, given by way of example only, to enable one skilled in the art to readily practice the invention singly or in combination as described hereinafter with reference to the accompanying drawings. In the detailed drawings, like reference numerals indicate like components.

### DETAILED ASPECTS OF THE INVENTION

There are many tradeoffs in the design, manufacture, and utilization of a sealant for solar concentrators and related optical equipment. For those devices that utilize internal lubrication [cf. U.S. Pat. Nos. 7,133,183, 7,130,102, and 6,976,445], it is judicious to seal these devices (equipment) to prevent egress of the lubricant or ingress of undesirable fluids. This is an important factor in their long term success. In the course of utilization of a sealant, one may also improve related properties without the incurrence of substantial cost. So a general strategy would be to ameliorate all external properties by incorporating such improvements into the sealant. In the course of implementation of this strategy, it became apparent that the application of this variegated sealant on the surface of the rotatable mirrored elements (balls) would also achieve beneficial effects. As is described here in detail, the objectives of the instant invention may be accomplished by any of a number of ways separately or in combination, as taught herein.

### Simple Protective Sealant

For simply sealing the equipment as well as reducing weathering and ultraviolet damage clear polyurethane, organic acrylate polymer sealant, or a polysiloxane, polymer sealant can be used on the top of the equipment. A non-clear polymer sealant can be applied to the underside and sides of the equipment as these surfaces need not be transparent. On the other hand, if the transparent sealant is also used on the bottom of the equipment, the potential is retained for turning the equipment over and utilizing the bottom as the new top side, if needed.

The protective sealant in either its pure and simple form, or as a layered structure as described in the various embodiments of the instant invention, may be applied by conventional methods such as dip coating, spraying, brushing, roll coating and other art-recognized techniques.

### High Index of Refraction Sealant

For some purposes related to reflection efficiency (transparency) and/or alignment [dielectric polarization mode in a Fresnel reflection solar concentrator [cf. Mario Rabinowitz, U.S. Pat. No. 7,187,490] it is desirable to have a high index of refraction. A sealant film with high refractive index has to be selected depending on the refractive index of the substrate material. Refractive index varies with a mixing amount or a mixing ratio of the inorganic fine particles. When there is a difference in refractive index between the substrate material and the sealant film, reflected light from an interface between the sealant and the equipment and reflected light from the surface of the sealant interfere with each other to generate interference fringes. For this reason, it is preferable that the refractive index of the sealant approximately equals the refractive index of the substrate. As the refractive index gets larger, an interference fringe is more likely to result than for low index of refraction. When the refractive index of the substrate exceeds 1.60, it is necessary to make the refractive index of the sealant film closer to the refractive index of the substrate.

Examples of plastics having a high refractive index can include a polyurethane resin obtained by addition-polymerizing a polyisocyanate compound with a polythiol and/or a sulfur-containing polyol and an episulfide resin obtained by addition-polymerizing an episulfide group with a polythiol and/or a sulfur-containing polyol. Of these base materials having various refractive indexes, a material having a refractive index of 1.57 or more is especially preferable. For example, a polyurethane resin and an episulfide resin having refractive indices of 1.60 and 1.70 respectively are preferable.

### Hard Sealant

In addition to performing the function of a sealant, mixing in hard filler particles makes the sealant hard and tough. By adjusting the thickness of the sealant film and the concentration of hard filler particles, a light transmittance in excess of 80% can be achieved. One preferred method of curing is by exposing the sealant to ultraviolet light in excess of 10 minutes and generally less than ˜ hours. Bonding can also be carried out by heating the substrate for 10 minutes to 10 hours at a temperature of 70 degrees centigrade or more (e.g., up to about 300 to 400 degrees centigrade). Preferably this is done for about 1 hour at about 115 degrees centigrade. The resulting hard film provides scratch resistance, chemical resistance, solvent resistance, and impact resistance.

The sealant hardness is achieved in accordance with the instant invention by adding fine silica, zirconium oxide, or alumina particles having an average diameter of from about 100 to about 5000 Angstroms; and an aluminum chelate compound. The sealant compositions of the invention are assembled by dispersing and mixing the hard filler particles in the silicon hard sealant composition. If desired, surfactants, thixotropic agents, organic polymers, inorganic fine zirconium oxide, or carborandum particles, metallic powder, curing catalysts, etc. may be added to the sealing solution as desired. Sols of zinc oxide, silicon dioxide, aluminum oxide, titanium oxide, zirconium oxide, tin oxide, beryllium oxide, antimony oxide, tungsten oxide, cerium oxide and the like may be utilized

A silicon compound that is used in the sealing compositions includes one or more silane compounds that are admixed. One of the following group of silane compounds in Group I may be hydrolyzed in the formation of a Hard Sealant:

### Group I:

vinyltrimethoxysilane,
vinyltriethoxysilane
ethylenediaminopropyltrimethoxysilane
gamma-aminopropyltrimethoxysilane
gamma-glycidoxypropyltrimethoxysilane
gamma-glycidoxypropyltriethoxysilane
gamma-glycidoxypropylmethyldimethoxysilane
gamma-glycidoxypropylmethyldiethoxysilane
beta-glycidoxyethyltrimethoxysilane
beta-(3,4-epoxycyclohexyl)ethyltrimethoxysilane
gamma-(3,4-epoxycyclohexyl)propyltrimethoxysilane
gamma-methacryloxypropyltrimethoxysilane
gamma-methacryloxypropylmethyldimethoxysilane
phenyltrimethoxysilane
gamma-mercaptopropyltrimethoxysilane
(2,3-epoxypropoxy)methyltrimethoxysilane

A second group (admixture set) of silane compounds corresponding to Group I silane compounds may be hydrolyzed in the formation of a Hard Sealant:

### Group II:

tetramethoxysilane
tetraethoxysilane
tetrapropoxysilane
tetrabutoxysilane
methyltrimethoxysilane
methyltriethoxysilane
methyltripropoxysilane
methyltributoxysilane
ethyltriethoxysilane
propyltriethoxysilane
butyltriethoxysilane.

The above 2 Groups of silane compounds are easily hydrolyzed in water or in an aqueous solution including nitric acid, sulfuric acid, acetic acid, phosphoric acid or the like. The hydrolysis may take place in the presence or absence of a solvent, such as an alcohol. These silane compounds are generally mixed in a solvent, such as an alcohol, ketone, ester, ether, cellosolve, organic halide, carboxylic acid, aromatic compound, or mixtures thereof. In the presence of a co-soluble organic polymer, a curing catalyst and a surfactant, a thixotropic agent, inorganic fine powders of silica, zirconium oxide, alumina, carborandum, and the like, and sealing compositions including the silane compounds provide suitable coatability properties, such as its leveling property, viscosity and drying.

The hardness portion of the sealing compositions utilized in accordance with the invention may be fine silica, zirconium oxide, or alumina particles having an average diameter of from about 100 to about 5000 Angstroms; and an aluminum chelate compound. The sealing compositions of the invention are prepared by dispersing and mixing the hard filler particles in the silicon hard sealing composition. If desired, surfactants, thixotropic agents, organic polymers, inorganic fine silica, zirconium oxide, alumina, carborandum particles, Titanium dioxide, Indium-Tin dioxide, silicon nitride, metallic powder, curing catalysts, etc. may be added to the sealing solution as desired.

### Hydrophobic Sealant

A lubricious hydrophobic outer layer is readily bonded to the just previously described Hard Sealant Layer. The lubricious hydrophobic outermost layer, together with the hard antiabrasive Substrate Binder layer, form a sealant and a wear-resistant surface on the substrate i.e. the equipment. The lubricious hydrophobic sealing layer preferably is formed of a hydrophobic organic lubricant selected from the group consisting of fluorocarbons (such as a perfluoropolyether), fatty acids, and fatty acid esters. The lubricious hydrophobic sealing layer needs to be from 50 to about 500 Angstroms thick.

The hydrophobic organic lubricant used to form the lubricous layer for the present invention can be a topical lubricant, such as used to reduce friction and wear of rigid bodies. However, the term “lubricant” as used herein is intended to encompass materials that accomplish the intended result of forming a hydrophobic wear-resistant surface on the body, whether or not those materials are conventionally employed as lubricants. Fatty acids and fatty acid esters are excellent boundary lubricants. Esters such as tridecyl stearate, butyl stearate, butyl palmitate, stearic acid, and myristic acids are commonly used lubricants and can be used to carry out the present invention. Fluorocarbons (i.e. fluoropolymers) such as perfluoropolyethers (PFPEs) are among the more chemically stable lubricants, and are particularly preferred.

Examples of suitable fluorocarbons include, but are not limited to, fluoropolyethers, fluoroacrylates, fluoroolefins, fluorostyrenes, fluoroalkylene oxides (e.g., perfluoropropylene oxide, perfluorocyclohexene oxide), fluorinated vinyl alkyl ethers and the copolymers thereof with suitable comonomers, wherein the comonomers are fluorinated or unfluorinated. Generally preferred are perfluorinated fluoropolymers (i.e., perfluoropolymers), with the term “perfluorinated” as used herein meaning that all or essentially all hydrogen atoms on the polymer are replaced with fluorine; and fluoropolyethers. Most particularly preferred are perfluoropolyethers; and fluoropolyethers or perfluoropolyethers with one or two end terminal hydroxy groups.

### Substrate Binder Layer

There may be instances where any or all of the forms of the sealant described above, do not bind well with the substrate i.e. the surface of the equipment. In this case one or more Binder Layers may be necessary. The Substrate Binder Layer is chosen to make a good bond with both the substrate and the next adjacent sealant layer. If necessary to facilitate a good bond with the next sealant layer, another Binder Layer may be added that bonds well with the bottom and the next adjacent sealant layer.

Thus one embodiment of the instant invention is a sealant having a hard antiabrasive Substrate Binder Layer which bonds well to the substrated and contains hard powders. A lubricious hydrophobic sealing layer is bonded to the Substrate Binder Layer, with the hard antiabrasive layer and the lubricious hydrophobic sealing layer together forming the wear-resistant surface layer formed on the surface of the equipment A preferred embodiment of the instant invention consists of a hard anti-abrasive Substrate Binder Layer which is vacuum deposited and comprises a material of the general formula M-O—C—H—N (wherein M is preferably selected from the group consisting of silicon, titanium, tantalum, germanium, boron, zirconium, aluminum, hafnium and yttrium). The hard antiabrasive substrate binder layer is from 1 to 10 microns thick.

The Substrate Binder Layer of this invention can be deposited by a number of processes, particularly vacuum and/or plasma deposition processes such as physical vapor deposition, sputtering, vacuum evaporation, and plasma enhanced chemical vapor deposition (plasma deposition processes are to be considered as vacuum deposition processes herein). The process may utilize, for example, hydrocarbon, metal or metalloid hydrocarbon feed compounds (typically feed gases) introduced with or without argon or other inert gas; energized into a plasma by direct current, radio frequency, microwave, enhanced plasmas or by hollow cathode magnetron energy sources. The energized precursor (with or without energized argon or other inert gas) is promoted into an excited state, producing ionic fragments and molecules in an excited state, which bombard and reconstruct on surfaces to produce a hard amorphous sealant. Numerous different types of materials, ranging from organic to inorganic, can be formed as a layer by these processes. Depending upon the process conditions, the films that are produced can be diamond-like, and comprise a member of the class of materials known as Diamond-Like Carbon. Diamond-Like Carbon is the generic name for a family of materials in which the molecular backbone is primarily carbon, with some hydrogen attached. The precursor and the process conditions determine the specific compositions and properties. For example, ordinary hydrocarbons can be used to produce films of hydrogenated amorphous carbon known as Diamond-Like Carbon.

The Substrate Binder Layer can be—but need not be—a material devoid of alkali metal atoms and fluorine, and may be a material selected from the group consisting of silicon nitride, titanium nitride, tantalum nitride, hafnium nitride, zirconium nitride, boron nitride, yttrium oxide, yttrium nitride, germanium oxide, hafnium oxide, silicon oxide, silicon dioxide, tantalum oxide, titanium oxide, zirconium oxide, silicon carbide, germanium carbide, titanium carbide, mixtures thereof, and chemically bonded combinations thereof. Additional examples of compounds suitable for the substrate binder layer include silicon oxynitride, silicon carbonitride, boron oxide, boron nitride, aluminum oxide, aluminum nitride, titanium dioxide, tantalum oxide, germanium oxide, germanium nitride and germanium carbide—including mixtures and chemically bonded combinations thereof.

### BRIEF DESCRIPTION OF THE DRAWINGS

FIG. 1 is a cross-sectional view of an ensemble of rotatable mirrored elements which are constituents of a solar concentrator or similar equipment which is enclosed in three layers of sealant.

FIG. 2 is a cross-sectional view of a single mirrored element that is circumscribed by one layer of protective sealant.

FIG. 3 is a cross-sectional view of a Fresnel lens which is covered with three layers of protective sealant.

### DETAILED DESCRIPTION OF THE PRESENTLY PREFERRED EMBODIMENTS

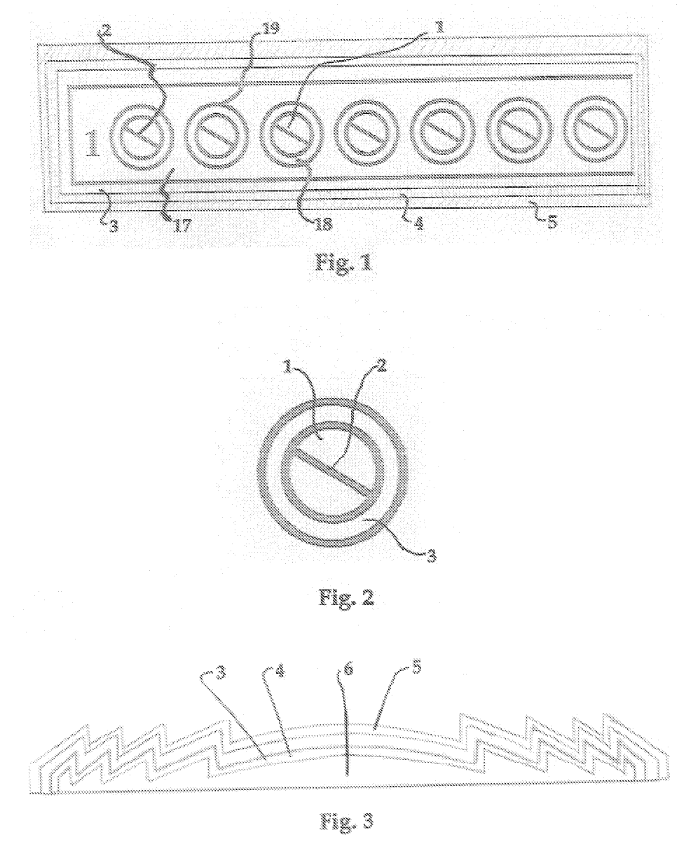

FIG. 1 is a cross-sectional view of an ensemble of rotatable elements (balls) 1, each with a mini- or micro-mirrored surface 2 to reflect incident light as focused concentrated light. The aggregate of the elements 1, together with their containment sheet 17, lubricating fluid 18, with each element 1 inside an encapsulating spherical cavity 19, are herein referred to as equipment 1 such as a solar concentrator, optical switch, etc. The inventor of this instant invention is the inventor of U.S. Pat. No. 7,133,183, in which the solar concentrator is described in detail; and U.S. Pat. Nos. 7,130,102 and 6,975,445 where similar optical equipment is described in detail.

Shown surrounding the equipment 1 is a Substrate Binder Layer 3, which is surrounded by a second Binder Layer 4, which in turn is surrounded by a Hydrophobic Sealant Layer 5. The Substrate Binder Layer 3 is chosen because it makes a strong bond to the substrate (i.e. the equipment). If the Hydrophobic Sealant Layer 5 can make a good bond to the Substrate Binder Layer 3 (or is not needed), then the second intermediate Binder Layer 4 is unnecessary. If the Hydrophobic Sealant Layer 5 is needed, but cannot make a good bond to the Substrate Binder Layer 3 then the second intermediate Binder Layer 4 serves to bond to the Substrate Binder Layer 3 and then to the outer the Hydrophobic Sealant Layer 5. In some instances, more than one intermediate Binder Layer may be necessary. The section DETAILED ASPECTS OF THE INVENTION gives a detailed description of the composition and functionality of the various layers. Additional details are as follows.

The sealant composition for the equipment in accordance with the invention includes an organic silicon compound and/or its hydrolyzate. Improved resistance to deterioration appears to be due to improved curing of the sealing composition. This results in increasing the cross linking rate of the silane compounds in the sealing composition. The resulting hard film sealant provides scratch resistance, chemical resistance, solvent resistance, and impact resistance. The implementation is by conventional sealing processes. These include dipping, spraying, spin coating and flow coating to form the sealant layer on the surface of the equipment. The sealant layer is then dry-heated to cure it. The required heating time and temperature vary according to the characteristics of the base material to be sealed. Preferably, the thickness of the cured sealant is between about 1 to 30 microns. A cured sealant layer of less than 1 micron in thickness will usually not provide a sufficient abrasion resistant sealant, whereas a sealant of 30 microns thickness is sufficient for abrasion resistance. A sealant of 100 microns thickness is adequate for most sealing purposes.

In one embodiment of the invention, the sealant composition includes a silane compound of Group I which includes an epoxy group or it is admixed with a compound containing an epoxy group and an epoxy-curing catalyst. In this case, silane from Group I of silane compounds formula is admixed with the epoxy compound. The epoxy compound is selected from mono-, di-, tri- and tetra-glycidyl ethers which are formed from polyhydric alcohols, such as (poly)ethyleneglycol, (poly)propyleneglycol, glycerol, neopentylglycol, 1,6-hexanediol, trimethylolpropane, pentaerythritol, diglycerol, sorbitol, bisphenol A which may include remaining —OH groups, and unsaturated fatty acid compounds such as oleic acid wherein the double bonds are totally or partially epoxiated.

A polyurethane clear sealant, an organic acrylate polymer sealant, or a polysiloxane polymer sealant is desirable to seal in lubricants and other volatiles as well as reducing weathering and ultraviolet radiation damage of equipment. Sealant implementation of the surface layer can be formed chemically, by vacuum deposition, preferably by plasma-enhanced chemical vapor deposition Organic acrylate polymer sealant or polysiloxane polymer sealants, also offer a significant improvement in abrasion resistance relative to unsealed equipment. Similarly inorganic hard sealants deposited directly on the equipment can also act as protective layers to improve abrasion resistance. Hard sealants subjected to thermal and mechanical stresses should not crack as a stress release mechanism if the equipment is subjected to various heating/cooling cycles; nor should they delaminate from the optical equipment substrate.

A less effective sealant may be used for some purposes such as one comprising an organic or inorganic compound, an adhesion promoter layer, an antireflection layer formed from colloids of silica, zirconium oxide, alumina, or carborandum in a siloxane binder; a silazane coupling layer, and an outer antiabrasion layer formed by the solvent deposition of a fluorinated polymer such as polytetrafluoroethylene (PTFE known as Teflon). The antiabrasion property relies solely on the antifriction properties of the Teflon polymer, and is not itself resistant to gouging or scratching by forcefully applied abrasive particles which penetrate into the antiabrasion layer.

FIG. 2 is a cross-sectional view of a single element (ball) 1 containing a mirrored surface 2 that is circumscribed by one layer of protective sealant 3. The protective sealant 3 is described in the section DETAILED ASPECTS OF THE INVENTION where a detailed description of the composition and functionality of each layer is presented so that a layer may be chosen with the necessary and proper properties for use on the elements 1. More than one layer may be used if desired. Additional details are as follows.

It was found that a superior composition contains a hydrolyzate of an organosilicon compound having a specific structure, specific metal oxide fine particles, a polyurethane and a curing agent. This can give a Hard Sealant layer which not only has sufficient adhesion and flexibility but also has excellent scratch resistance (abrasion resistance) when applied to the surface of a mirrored element (ball) 1 and cured with ultraviolet light, heat, or a chemical curing agent.

To increase the wear lifetime of the elements (balls) 1 a hard sealant composition comprised of a hydrolyzate of a specific alkoxysilane compound; fine particles of an oxide of silicon; aluminum, tin, antimony, zirconium, tungsten or titanium or composite fine particles made of oxides of one or more of these; a polyurethane; and a curing agent. An advantageous curing agent is aluminum acetyl acetonate.

Specific examples of the inorganic oxide fine particles include sols of zinc oxide, silicon dioxide, aluminum oxide, titanium oxide, zirconium oxide, tin oxide, beryllium oxide, antimony oxide, tungsten oxide, cerium oxide and the like, and these may be used either singly or as a mixed crystal of two or more thereof. As a composite sol of two or more thereof, for example, a composite sol of tin oxide and tungsten oxide can be employed. The size of metallic particles is important because it is an important factor in determining the transparency of a hard sealant film. The metallic particle size has to be 1000 Angstroms or less, and a size of from 10 to 500 Angstroms is preferable. The percentage of metallic oxide particles greatly influences hardness and toughness of the hard sealant film. It is preferable that the metallic oxide particles be between 40 to 60% by weight relative to the resin or polymer components of the Sealant.

In the sealant composition of the instant invention, the polyurethane as component is not critical as long as it is a transparent liquid polyurethane. It can be selected from a one-part thermoplastic polyurethane, a two-part thermoplastic polyurethane and a thermosetting polyurethane. In view of weathering resistance, a non-yellowing polyurethane is preferred. Examples of the one-part thermoplastic polyurethane include a trade name “Coatron KYU-1” and a trade name “Sanprene SP-75”. Concerning the two-part thermoplastic polyurethane, the polyol component includes polyesterpolyol and acrylpolyol, and the isocyanate component includes hexamethylenediisocyanate, xylylenediisocyanate, hydrogenated xylylenediisocyanate, 4,4′-methylenebisdicyclohexyldiisocyanate and isophoronediisocyanate. Care must be taken, so that the polyurethane is not incompatible with an organic silicon compound and a metal oxide sol.

Even if a polyurethane is added in a small amount, or even if a sealant composition forms a homogeneous transparent solution, a transparent sealant is not easily formed when the sealant is formed by curing, since fogging or phase separation is liable to take place.

The problem of fogging and phase separation of the sealant can be overcome by mixing the organosilicon compound of the general formula as a precursor. The polyurethane component may be used with a solvent, hydrolyzing the organosilicon compound, thereby obtaining a solution of a hydrolyzate of the organosilicon compound of the general formula; and the polyurethane as component; and then adding the fine particles as a component; and finally a curing agent the solution. Examples of the curing agent include various acids, bases, metal salts of organic acids, metal alkoxides and metal chelate compounds, giving a wide variety of choices for the selection of a proper.

As to the amounts of powder in the sealing composition of the instant invention, the amount of the metal oxide fine particles in parts by weight of the hydrolyzate of the organosilicon compound is generally in the range from 1 to 200 parts by weight, and preferably 10 to 100 parts by weight. When less than 1 part by weight of hardening powders is used, a cured sealant may have insufficient hardness. When it exceeds ˜50 to 200 parts by weight, gelation may result. The amount of the polyurethane as component is generally in the range of from 0.1 to 100 parts by weight, preferably 0.5 to 50 parts by weight. When the amount of the polyurethane is less than 0.1 part by weight, a cured sealant may have insufficient adhesion to a substrate. When the polyurethane exceeds 100 parts by weight, the transparency of a cured sealant tends to decrease. Further, the amount of the curing agent as component (D) is generally in the range of from 0.1 to 50 parts by weight, preferably 1 to 20 parts by weight. When the amount of the curing agent is less than 0.1 part by weight, curing may be insufficient.

In addition to the above components the sealing composition of the present invention may contain various additives as for example, a resin such as an epoxy resin, an ultraviolet absorbent, a photo-stabilizer such as a hindered-amine-containing photo-stabilizer, an antioxidant and a surfactant as required for improving the sealant composition in various properties, so long as the physical properties of a cured sealant are not impaired.

The method of applying the above sealant composition to the element (ball) 1 surface is not specially limited, and it can be selected, for example, from general methods such as a dipping method, a spin coating method or a spraying method as required.

FIG. 3 is a cross-sectional view of a Fresnel lens 6 which is covered with three layers of protective sealant. The section DETAILED ASPECTS OF THE INVENTION gives a detailed description of the composition and functionality of the various layers. The Fresnel lens gathers light over a large area, and focuses it down to the small area of a high-grade solar cell or other energy conversion device. Fresnel lenses have been used in Spain, in the United States of America, and elsewhere to provide high concentration up to 1000× for high-grade photovoltaic solar cells with efficiency from 35% to 40%.

Shown covering the Fresnel lens 6, is a Substrate Binder Layer 3, which is covered by a second Binder Layer 4, which in turn is covered by a Hydrophobic Sealant Layer 5. The Substrate Binder Layer 3 is chosen because it makes a strong bond to the substrate (i.e. the Fresnel lens). If the Hydrophobic Sealant Layer 5 can make a good bond to the Substrate Binder Layer 3 (or is not needed), then the second intermediate Binder Layer 4 is unnecessary. If the Hydrophobic Sealant Layer 5 is needed, but cannot make a good bond to the Substrate Binder Layer 3 then the second intermediate Binder Layer 4 serves to bond to the Substrate Binder Layer 3 and then to the outer Hydrophobic Sealant Layer 5. In some instances, more than one intermediate Binder Layer may be necessary. It is generally sufficient to seal only the Fresnel lens 6 as shown. However, in some instances it may be desirable to seal the entire Fresnel lens assembly. The section DETAILED ASPECTS OF THE INVENTION gives a detailed description of the composition and functionality of the various layers. Since the Fresnel lens 6 generally operates at a magnification (concentration) level, it is preferably utilized with a high index of refraction material which is covered with a HIGH INDEX OF REFRACTION SEALANT as described in detail in the subsection of that name. In accordance with the instant invention, the refractive index of the film formed on a substrate can be controlled by varying the composition of the fine particulate compound oxide and the quantity ratio of the matrix to the compound oxide in the sealant solution. Additional details are as follows.

For sealing a Fresnel lens, the instant invention relates to a sealant film which is colorless and transparent, has a high refractive index and is excellent in high temperature and hot water resistance, weathering resistance, light resistance, scuffing resistance, abrasion resistance, impact resistance, flexibility, and adhesion to a substrate made of glass or plastic. This aspect of the instant invention relates to a hard sealant film of a high refractive index equal to or greater than that of the substrate Fresnel lens that is free from interference fringes.

The resin is filled with fine particulate compound oxides such as Al oxide, Ti oxide, Zr oxide, Sn oxide or Sb oxide, having a high refractive index. Other embodiments entail preparing a compound sol of titanium dioxide and cerium dioxide. A hard Sealant film containing compound oxide fine particles of Ti and Fe or compound oxide fine particles of Ti, Fe and Si is also possible.

Surface treatment with an organosilicon compound or an amine compound is preferable the above fine particulate compound oxides. This stabilizes the dispersed state of the fine particulate oxides for a long period of time in the sealant solution containing the compound oxide and the matrix, even when an ultraviolet curing resin is used as the matrix. Furthermore, the fine particulate compound oxide surface modified with an organosilicon compound or an amine compound has improved reactivity with and affinity for the matrix, so that a film formed from a sealant solution containing the surface-treated fine particulate compound oxide is superior in hardness, transparency and scuffing resistance to a film formed from a sealant solution containing a fine particulate compound oxide without the surface treatment. Additionally, the surface-treated fine particulate compound oxide has much more improved affinity for a solvent used in the sealant solution, as compared with compound oxide without the surface treatment.

As the matrix in the sealant solution of the invention, conventional sealant resins, such as acrylic resins, melamine resins, ultraviolet curing resins, urethane resins and phosphagene resins, can be utilized. At least one compound selected from organosilicon compounds can also be utilized. An organic solvent may be used in the sealant solution of the invention to adjust the solid concentration in the sealant solution or control surface tension, viscosity and evaporation rate of the sealant solution. For modifying the surface of the fine particulate compound oxide, any organosilicon compound known as a silane coupling agent is employable, and it may be properly selected depending, for example, on the type of a matrix or a solvent used in the sealant solution of the invention.

Organic solvents which can be used singly or in combination in the instant invention include alcohols, such as methanol, ethanol and isopropyl alcohol; cellosolves, such as methyl cellosolve and ethyl cellosolve; glycols, such as ethylene glycol; esters, such as methyl acetate and ethyl acetate; ethers, such as diethyl ether and tetrahydrofuran; ketones, such as acetone and methyl ethyl ketone; halogenated hydrocarbons, such as dichloroethane; aromatic hydrocarbons, such as toluene and xylene; carboxylic acids; and N,N-dimethylformamide.

The instant invention includes an abrasion-resistant sealant for optical equipment, and a method for sealing the equipment such as a Fresnel lens with an abrasion-resistant sealant. The method includes forming the sealant on a face of a mold that is substantially cured and capable of being adhered to the equipment. The sealant composition consists of reactants, approximately 70% to 95% of which have at least triacrylate functionality and approximately 5% to 30% of which have diacrylate functionality, a photoinitiator, a polymerization inhibitor reactive with oxygen, a silane adhesion promoter and an acid to activate the adhesion promoter. The sealant is applied to the face of the mold and forms a substantially uniform sealant and is then subjected to ultraviolet light in an oxygen-containing environment such that a hard abrasion-resistant sealant is formed on the mold. The mold is then filled with the equipment (e.g. Fresnel lens) forming composition which is reactive with acrylate groups of the sealer at a sealant/Fresnel lens interface. The Fresnel lens (or other equipment)-forming composition is permitted to cure in the mold to form a Fresnel lens having a hard abrasion-resistant sealer. No further post curing treatment is needed since the sealer is at maximum abrasion resistance when the Fresnel lens leaves the mold.

For purposes of the instant invention, the term prepolymer means monomer, oligomer and other reactants which react to form a polymeric material. A primary sealer composition of the instant invention consists of reactants having at least a triacrylate functionality. In other words, the primary sealer reactant includes predominantly monomers or oligomers having at least 3 or more acrylate-functional groups per molecule. A preferred primary component having at least triacrylate functionality includes monomer or oligomer constituents that form pentaerythritol tetraacrylate (PETA), dipentaerythritol monohydroxy pentaacrylate (DPMHPA), trimethylolpropane trimethylacrylate (TMPTA), pentaerythritol triacrylate, blends or oligomers thereof, as well as other prepolymers having at least triacrylate functionality.

Utilization of highly efficient photoinitiators to cure the sealant composition is preferable. Suitable photoinitiators include aroketones and aromatic-containing ketones. The preferred photoinitiator of the present invention is 1-hydroxy-cyclohexyl-phenyl ketone, which is employed at concentrations of 0.1-10.0% by weight of the resin solids and most preferably in the range of 2-5% by weight of the resin solids. The preferred photoinitiator is marketed under the designation of IRGACURE 184 by Ciba-Geigy.

### Material Issues, Advantages, and Alternative Embodiments

The optically transparent sheet in which the mirrored elements, i.e. balls, spheres or cylinders are imbedded, need not be an elastomer, though a silicone elastomer is presently preferred. The sheet may be made of plastics such as polyethylene, polystyrene or plexiglass. Encapsulation can be achieved with the encapsulant molten or dissolved in a volatile solvent. An uncured rigid material such as an epoxy can be used as the encapsulant binder provided that it is light transparent. It is imperative that the material of the sheet absorb the dielectric plastizer liquid lubricant more readily than do the balls in order to form the liquid filled cavities around each ball. When the material of the gyricon sheet binder is an elastomer, the spheres can be plastics such as polyethylene or polystyrene which do not absorb the plasticizer as readily as elastomers.

Another encapsulation procedure may employ layers of photoresist suitably etched and then hardened to provide chambers for each ball creating spherical shells or at least egg crate cubicles for the balls. Another less preferred procedure would be to put an ensemble of small micro-mirrored balls mixed together with an ensemble of larger micro-mirrored balls. With vibration, the larger balls compact into a high packing-fraction array. With a careful choice of relative sizes and numbers of balls that may easily be calculated, the micro-mirrored balls will fall into the interstitial locations between the larger spheres. Lubricant can be added, and the system sealed between sheets. Thus the small micro-mirrored balls could rotate with little friction and be confined to eliminate undesirable translational motion.

When the material of the binder is a plastic, the balls must be of a material such as glass which does not absorb the liquid, or absorbs the dielectric liquid much less than does the plastic. Additional reasons for using glass balls are its superior durability with respect to ultraviolet light; its excellent optical properties such as high transparency; and its low cost. Though not as good as glass, silicone has high ultraviolet light durability as well as good electrical properties. For example, electrical cables impregnated with silicone additives better withstand electrical and water treeing. Other possible polymers that may prove promising singly, or as part of a laminar structure, are TPX (4-methyllpentene-1), Aurem (Polyimide), and SPS (Syndiotactic Polystyrene). An alternative approach to a single sealant material uses these and non-thermoplastic polymers in a laminar film form. PQ-100 (Polyquinoline) or Isaryl 25 can also be used in laminar form. Cross-linkable silicone or 1,4-polybutadiene based resin can be used to permeate the sealant material and fill unwanted voids, should they be present.

One embodiment of the instant invention has a Sealant composition consisting of reactants, approximately 70% to 95% of which have at least triacrylate functionality and approximately 5% to 30% of which have diacrylate functionality, a photoinitiator, a polymerization inhibitor reactive with oxygen, and a silane adhesion promoter and an acid to activate the silane adhesion promoter.

Another embodiment of the instant invention puts an abrasion resistant Sealant on a substrate of plastic. The Sealant consists of at least 30% by weight of polyfunctional compounds selected from the group consisting of polymethacryloyloxy compounds having at least three methacryloyloxy groups in one molecule with the molecules having a molecular weight of 250 to 800 and polyacryloyloxy compounds having at least 3 acryloyloxy groups in each molecule, and a fluorine-containing surfactant, in which the fluorine atom is bonded to a carbon atom. The Sealant is either applied to the already molded plastic substrate or is applied to the mold and the sealer is cured by ultraviolet radiation in a nitrogen atmosphere.

Another embodiment of the instant invention is an in-mold applied hard Sealant composition equipment. The Sealant composition includes a pentaerythritol-based polyacrylate in combination with a cellulose ester or vinyl chloride-vinyl-acetate-containing copolymer (the function of which is to reduce surface oxygen inhibition during cure) followed by ultraviolet actinic radiation to form a cured abrasion-resistant Sealant. However, in order to obtain a satisfactory degree of crosslinking in the presence of ultraviolet radiation in an ordinary oxygen-containing environment, these compositions contain 10% or more of a cellulose ester or a vinyl chloride-vinyl acetate. Consequently, though useful, these sealants do not achieve as high an abrasion resistance as described above for harder sealants.

Yet another embodiment of the instant invention employs an ethylenically-reactive-unsaturated monomer/oligomer-containing formulation which is applied to a mold surface. Solvents in the formulation are volatilized and the formulation is brought to an intermediate degree of crosslinking by either heat or actinic radiation to form a dry tack-free film having sufficient adhesion and cohesive strength to the mold surface to permit further processing and to precisely replicate the mold surface so as to be free of optical defects. The sealer at this point is in a soft-nonabrasion-resistant “gelled” polymer state. The equipment (e.g. Fresnel lens) forming material is then introduced into the mold and the Fresnel lens forming material along with the sealer composition is then subsequently crosslinked or hardened by heat. The Fresnel lens is removed with the sealer adhering to the fully polymerized plastic lens, both being in a fully cured state.

Polymerization of the monomer occurs by radiation of UV light while the lens is encased in a curing chamber. The spin coater has the following advantages: Excess monomer is collected in a dish away from UV exposure and is readily disposed of. The substrate is revolved at a high rate of speed during the application of the sealant to achieve a uniform coating of monomer. The curable liquid solution is composed of a mixture of ethylenic unsaturated monomers such as acrylate monomers and other monomers curable by UV radiation, together with UV cure agents such as free radical initiators, low boiling organic solvents such as alcohols and/or ketones and flow agents such as fluorocarbons.

While the instant invention has been described with reference to presently preferred and other embodiments, the descriptions are illustrative of the invention and are not to be construed as limiting the invention. Thus, various modifications and applications may occur to those skilled in the art without departing from the true spirit and scope of the invention as summarized by the appended claims together with their full range of equivalents. It is to be understood that in said claims, ingredients or compounds recited in the singular are intended to include compatible mixtures of such ingredients wherever the sense permits. It is also to be understood that the following claims are intended to cover all of the generic and specific features of the invention herein described, and all statements of the scope of the invention which, as a matter of language, might be said to fall there between.

1. Sealed solar energy equipment comprising:
a) an outer surface;
b) inner elements;
c) said outer surface having at least one optically transparent side;
d) at least one layer of sealant on said outer surface;
e) said sealant being optically transparent on at least that portion of said outer side having an optically transparent surface;
f) said optical transparency of said sealant being in the wavelength range of about 2000 to approximately 7500 Angstroms; and
g) said sealant forming a bond to said outer surface.

2. The equipment of claim 1 wherein one layer is a hard sealant.

3. The equipment of claim 1 wherein one layer is a high index of refraction sealant.

4. The equipment of claim 1 wherein one layer is a hydrophobic sealant.

5. The equipment of claim 1 wherein at least one layer is a binder layer.

6. The equipment of claim 1 wherein at least one layer is bonded to an inner element.

7. The equipment of claim 1 wherein said sealant comprises at least a hard sealant layer on a surface of the equipment and a hydrophobic layer on the hard sealant layer, the coating composition comprising at least one compound from the following groups 1) silane group; 2) a hydrolyzate of an organosilicon compound group; 3) an alkenyl group; 4) an aryl group; 5) an aralkyl group; 6) a methacryloxy group or an epoxy group; 8) a polyurethane group; 7) particles of at least one oxide of an element selected from the group consisting of silicon, aluminum, tin, antimony, zirconium, tungsten and titanium; and 9) a curing agent such as a metal chelate compound.

8. A method for maintaining the integrity of solar energy equipment comprising the steps of:
a) bonding a hard sealant to the surface of said equipment;
b) said sealant being optically transparent on at least that portion of said equipment having an optically transparent surface;
c) said optical transparency of said sealant being in the wavelength range of about 2000 to approximately 7500 Angstroms;
d) bonding said sealant strongly to said outer surface; and
e) bonding at least one additional layer of sealant from the group: high index of refraction layer, hydrophobic layer, and substrate binder layer.

9. The method of claim 8 wherein said sealant provides protection for the surface of a Fresnel lens.

10. The method of claim 8 comprising an optically transparent sealant having a hardened surface portion; a hard antiabrasive substrate binder layer formed on said surface portion comprising a SiOₓH_{y} layer formed on said surface portion and a SiOₓC_{y}Hₓ layer formed on said SiOₓH_{y} layer; sols of zinc oxide, silicon dioxide, aluminum oxide, titanium oxide, zirconium oxide, tin oxide, beryllium oxide, antimony oxide, tungsten oxide, cerium oxide and the like and a lubricious fluoropolyether coating layer bonded to said substrate binder layer by the process of heating or subjecting said sealant composition to ultraviolet radiation; with said hard antiabrasive substrate binder layer and said lubricious fluoropolyether coating layer together forming said wear-resistant optically transparent sealant.

11. The method of claim 8 comprising an optically transparent sealant having an organosiloxane-based hard coating film formed on a surface of said equipment as a first layer, an inorganic oxide-based antireflection film formed on the hard coating film as a second layer, and a water-repellent thin film obtained by polycondensing an organosilicon compound and formed on the antireflection film as a third layer.

12. The method of claim 8 comprising an optically transparent sealant consisting of a film-forming sealant solution, a resin matrix, an organic solvent; wherein the resin matrix is at least one compound selected from organosilicon compounds, hydrolyzates thereof or partial condensates thereof, and wherein the coating solution further contains at least one component selected from the group consisting of a particulate oxide of at least one element selected from the group consisting of Si, Al, Sn, Sb, Ta, Ce, La, Fe, Zn, W, Zr In, W, and Ti, wherein at least one compound selected from the group consisting of polyfunctional epoxy compounds, polyhydric alcohols and phenols, polycarboxylic acids and anhydrides thereof; at least one compound is selected from hindered amine compounds; and at least one compound selected from the group consisting of amines, amino acids, metallic acetylacetonates, organic acid metallic salts, perchloric acid, salts of perchloric acid, acids and metallic chlorides.

13. The method of claim 8 comprising the step of individually sealing each element of an ensemble of optical elements that are indigenous inside the equipment that holds said ensemble.

14. Sealed optical equipment comprising:
a) an outer surface;
b) inner movable elements;
c) said inner movable elements in optical communication with the environment external to said optical equipment;
d) said outer surface having at least one optically transparent side;
e) at least one layer of sealant on said outer surface;
f) said sealant being optically transparent on at least that portion of said outer side having an optically transparent surface;
g) said optical transparency of said sealant being in the wavelength range of about 2000 to approximately 7500 Angstroms; and
h) said sealant forming a bond to said outer surface.

15. The equipment of claim 14 wherein one layer is a hard sealant.

16. The equipment of claim 14 wherein one layer is a high index of refraction sealant.

17. The equipment of claim 14 wherein one layer is a hydrophobic sealant.

18. The equipment of claim 14 wherein at least one layer is a binder layer.

19. The equipment of claim 14 wherein at least one layer is bonded to an inner element.

20. The equipment of claim 14 wherein one layer of sealant is chosen from the group: clear polyurethane, organic acrylate polymer, and polysiloxane
